(19) United States
(12) Patent Application Publication
(10) Pub. No.: US 2025/0056922 A1
(43) Pub. Date: Feb. 13, 2025

(54) QUANTUM-DOT-CONTAINING COMPOSITION, LIGHT-EMITTING ELEMENT, DISPLAY DEVICE, AND METHOD FOR MANUFACTURING QUANTUM-DOT-CONTAINING COMPOSITION

(71) Applicant: Sharp Display Technology Corporation, Kameyama City, Mie (JP)

(72) Inventors: Keisuke KITANO, Kameyama City, Mie (JP); Yoji MATSUDE, Kameyama City, Mie (JP); Yoshihiro UETA, Kameyama City, Mie (JP)

(21) Appl. No.: 18/718,014

(22) PCT Filed: Feb. 18, 2022
(86) PCT No.: PCT/JP2022/006533

§ 371 Date: Jun. 7, 2024

(51) Int. Cl. H01L 33/06; C09K 11/08; H01L 25/075

(52) U.S. Cl. CPC H01L 33/06; C09K 11/0805; H01L 25/0753

(57) ABSTRACT

A quantum-dot-containing composition contains: either quantum dots each having a surface provided with only one equivalent crystal plane, or quantum dots each having a surface provided with two or more different equivalent crystal planes; and one selected from (A), (B), and (C) below: (A) two or more compounds; (B) one or more compounds, and single atoms formed of one or more halogens or chalcogens; and (C) single atoms formed of two or more halogens or chalcogens.

### TECHNICAL FIELD

The disclosure relates to a quantum-dot-containing composition, a light-emitting element, a display device, and a method for manufacturing quantum-dot-containing composition.

### BACKGROUND ART

In the related art, active studies have been conducted to attempt to coordinate a halogen to quantum dots in order to improve quantum yield of the quantum dots. For example, Patent Document 1 describes that a haloid salt is bonded to at least a portion of a surface of quantum dots. Furthermore, Non-Patent Document 1 describes that bromine (Br) is coordinated to quantum dots, and Non-Patent Document 2 describes that chlorine (Cl) is coordinated to quantum dots. The effect of improving the quantum yield of the quantum dots is caused perhaps because strong electronegativity allows the halogen to tightly coordinate to the surface of the quantum dots.

### CITATION LIST

### Patent Literature

[Patent Document 1] United States Patent Application Publication No. 2015/0291422

### Non-Patent Literature

[Non-Patent Document 1] Efficient exciton generation in atomic passivated CdSe/ZnSquantum dots light-emitting devices Scientific Reports 6:34659 DOI: 10.1038/srep34659
[Non-Patent Document 2] Efficient and stable blue quantum dot light-emitting diode|Nature|Vol 586|15 Oct. 2020|387

### SUMMARY

### Technical Problems

The above known techniques still cannot improve the quantum yield of the quantum dot solution to a sufficient degree, which causes a problem that a light-emitting element whose light-emitting layer contains quantum dots suffers low external quantum efficiency (EQE).

An aspect of the disclosure sets out to increase the quantum yield of a quantum dot solution, and thus increase the EQE of a light-emitting element.

### Solution to Problems

In order to solve the above problems, a quantum-dot-containing composition according to an aspect of the disclosure includes: either quantum dots each having a surface provided with only one equivalent crystal plane, or quantum dots each having a surface provided with two or more different equivalent crystal planes; and one selected from (A), (B) and (C) below: (A) two or more compounds; (B) one or more compounds, and single atoms formed of one or more halogens or chalcogens; and (C) single atoms formed of two or more halogens or chalcogens.

A light-emitting element according to an aspect of the disclosure includes a light-emitting layer containing a quantum-dot-containing composition according to an aspect of the disclosure.

A display device according to an aspect of the disclosure includes a light-emitting element according to an aspect of the disclosure.

### Advantageous Effects of Disclosure

An aspect of the disclosure can increase the quantum yield of a quantum dot solution, and thus increase the EQE of a light-emitting element.

### BRIEF DESCRIPTION OF DRAWINGS

FIG. 1 is a table showing lattice constants of crystals of each of a core and a shell and lattice mismatch between the core and the shell.

FIG. 2 is a graph illustrating a relationship between a lattice mismatch rate and a critical thickness.

FIG. 3 is a cross-sectional view of an exemplary schematic configuration of a light-emitting element according to the present disclosure included in a display device according to the present disclosure.

FIG. 4 is a diagram illustrating a configuration of a main component of the display device according to the present disclosure.

FIG. 5 is a flowchart showing an exemplary method for manufacturing a quantum-dot-containing composition according to the present disclosure.

FIG. 6 is a perspective view of an ideal quantum dot with all surfaces terminated with (001) equivalent planes.

FIG. 7 is an image showing a state of halogen ligands viewed in a cross-section indicated by a broken line D1 in FIG. 6.

FIG. 8 is a perspective view of an actual quantum dot having (001) equivalent planes, (011) equivalent planes, and (111) equivalent planes.

FIG. 9 is an image showing a state of halogen ligands viewed in a cross-section indicated by a broken line D2 in FIG. 8.

FIG. 10 is an image showing a state of halogen ligands viewed in a cross-section indicated by a dot-and-dash line D3 in FIG. 8.

FIG. 11 is a pair of graphs showing a result of measuring a quantum yield (QY) and a fluorescence lifetime (τ) of quantum dot solutions in an example in which F ligands and halogen ligands other than the F ligands are mixed together and applied to InP quantum dots.

FIG. 12 is a pair of graphs showing a result of measuring a quantum yield (QY) and a fluorescence lifetime (τ) of quantum dot solutions in a comparative example in which various kinds of halogen ligands are applied alone to InP quantum dots.

FIG. 13 is a perspective view of another actual quantum dot having (001) equivalent planes, (011) equivalent planes, and (111) equivalent planes.

FIG. 14 is a diagram illustrating a relationship between defect density and kinds of halogens likely to be coordinated, showing a case where the defect density is high.

FIG. 15 is a diagram illustrating a relationship between defect density and kinds of halogens likely to be coordinated, showing a case where the defect density is low.

FIG. 16 is a diagram showing an image of a state in which two kinds of halogens are coordinated to a surface having high defect density, as viewed from the top.

FIG. 17 is a diagram showing an image of a state in which two kinds of halogens having slightly different ionic radii are coordinated to a surface having low defect density, as viewed from the top.

### DESCRIPTION OF EMBODIMENTS

### Detail of Study

The inventors of the disclosure have conducted extensive studies to solve the above problem, and, as a result, have achieved the disclosure. First, details of the studies will be described. Hereinafter, the description of the details of the studies (hereinafter referred to as “this description”) is intended to facilitate understanding of the disclosure, and shall not limit the disclosure. The description of the disclosure should be understood that materials, shapes, structures and manufacturing methods different from those in this description are also applicable to this description unless otherwise contradicting this description.

### 1. Quantum Dots

Quantum dots used for a light-emitting element are typically core-shell quantum dots in order to efficiently confine excitons. The quantum dots as a material to emit visible light mostly have a core diameter of approximately 20 nm or less, and a shell thickness of approximately 1 nm to 5 nm.

Other than CdSe, InP, and ZnSe, perovskite and chalcogenide are used as materials of the cores. When the materials are used for a light-emitting element as a pixel of a display panel, the materials are desirably Cd-free. Hence, InP, ZnSe, and perovskite are used as the materials. Furthermore, in order to confine excitons, the shells are desirably made of a material having a quantum level greater than that of the cores. Typically, the material is ZnS. The description below will be given with reference to a combination of a core formed of InP or CdSe and a shell formed of ZnS.

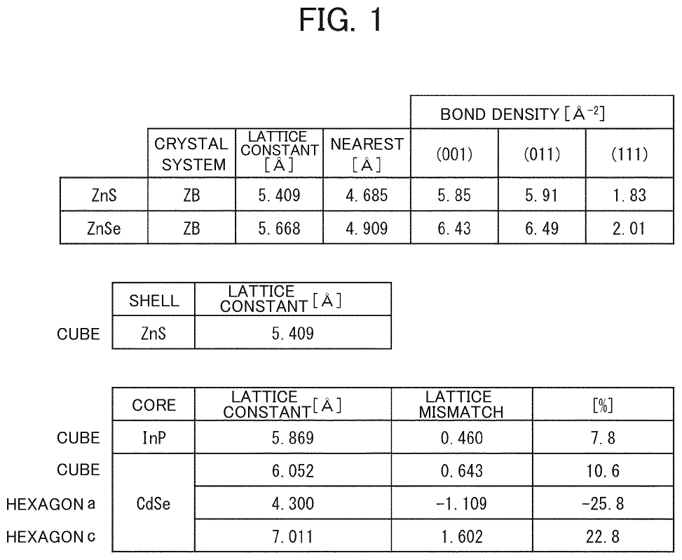

FIG. 1 is a table showing lattice constants of crystals of each of a core and a shell and lattice mismatch between the core and the shell. As shown in FIG. 1, a typical quantum dot is a cubic crystal. In such a case, a lattice mismatch rate between the core and the shell is as large as 7.8% for an InP core and a ZnS shell, and 10.6% for a CdSe core and a ZnS shell.

When two different crystals are epitaxially grown or when a different crystal is epitaxially grown on a certain crystal, it is known that a crystallographic defect develops often under a condition where a large lattice mismatch is observed. In particular, when the lattice mismatch rate exceeds 2%, a high-density defect develops. As a result, the obtained crystal is low in quality. The defect develops, depending on strain energy and elasticity of the crystal, and an upper limit at which the defect does not develop is referred to as a critical thickness.

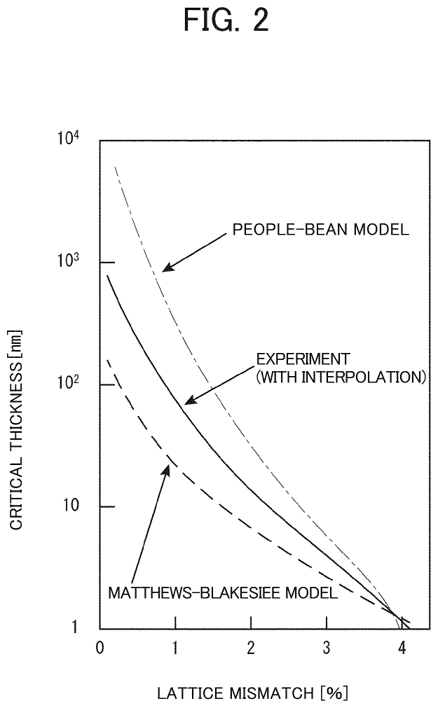

The lattice mismatch rate and the critical thickness have a relationship illustrated in FIG. 2, and the critical thickness rapidly decreases as the lattice mismatch rate increases. FIG. 2 is a graph illustrating a relationship between the lattice mismatch rate and the critical thickness. As illustrated in FIG. 2, the critical thickness is 10 nm or less at a lattice mismatch rate of approximately 2%, and 2 nm at a lattice mismatch rate of 4%. When the critical thickness is greater than those thicknesses, the crystallographic defect develops.

When the above factors are applied to the quantum dots, whether the shell develops the crystallographic defect can be determined by the lattice mismatch rate between the core and the shell and by the thickness of the shell. The quantum dots as a material to emit visible light mostly have a core diameter of approximately 20 nm or less, and a shell thickness of approximately 1 nm to 5 nm, depending on a bandgap of the bulk. As described before, the lattice mismatch rate is as high as 7.8% when the core is InP and the shell is ZnS, and as high as 10.6% when the core is CdSe and the shell is ZnS. The critical thickness is 1 nm or less.

As can be seen, typical quantum dots used for a light-emitting element have the shells containing many crystallographic defects, and the many defects are exposed on the surface of the shells; that is, on the surface of the quantum dots. Furthermore, if the surface of the quantum dots is terminated with two or more different crystal planes, the defect density varies depending on the difference in atomic density of each crystal plane. Hence, on a crystal plane having particularly high defect density, when ligands are coordinated at narrow intervals, and electrostatic interaction is strong between ligands, particularly between end groups coordinated to the quantum dots, many active defects might be left uncoordinated with the ligands.

### 2. Effect of Defects

When quantum dots are used for a light-emitting element, the defects of the quantum dots affect both light-emitting recombination of excitons and injection of carriers into the quantum dots. The defects serve as a non-light-emitting center, which decreases light-emitting recombination probability and, consequently, decreases the EQE of the light-emitting element. Furthermore, the defects on the surface of the quantum dots act as carrier traps, which decreases efficiency in injecting the carriers into the quantum dots, and also decreases the EQE. Hence, in order to improve the EQE, a control has to be imposed on influence of the defects contained in the quantum dots.

First, most directly, the defects may be reduced. However, as described above, the development of the defects significantly depends on the lattice mismatch rate of the crystal, and the reduction of the defects is very difficult in practice. As a second means, if the defects are successfully deactivated, the same effect can be expected as that of effectively reducing the defects. Practically, the second means is widely used. Quantum dots in practical use have the surface coordinated with organic ligands so that the defects on the surface are deactivated. The ligands with a molecular structure containing a halogen are considered to deactivate the defects more significantly. Hence, as described before, such ligands have been increasingly used in recent years. Furthermore, it has also been found out that a halogen element alone can deactivate the defects.

However, even if the quantum dots having the surface coordinated with the organic ligands are used for a light-emitting element, there is a serious problem that the EQE of the light-emitting element is low or the reliability of continuous energization is insufficient. Both problems are caused by loose and unstable bonding of the organic ligands coordinated to the defects on the surface of the quantum dots bond is loose and unstable, that multiple crystal planes with different defect density are found on the surface of the quantum dots, and by many defects left non-deactivated because of the crystal plane orientations.

Hence, the inventors of the disclosure have found that use of ligands, a specific element group, or a specific compound, which, first, tightly coordinate to defects on the surface of the quantum dots, and, second, readily bonds to each of a plurality of crystal plane orientations terminating the surface of the quantum dots, can increase the quantum yield of the quantum dot solution and enhance the EQE of the light-emitting element.

Specific examples of the element group include a halogen and a chalcogen. In the following description, a halogen is mainly described. Alternatively, the halogen may be replaced with a chalcogen as it is. Furthermore, in the description below, ligands are used. Alternatively, a specific element group or a specific compound may be used to bond to defects on the surface of the quantum dots.

Moreover, in the description below, if “ligands” or a substance possibly serving as “a substance to coordinate”, or a described substance is found together with the quantum dots, various interactions may take place to perform a desired function. Hence, the interactions do not have to be identified, and the presence of the substance together with the quantum dots can be understood as the quantum-dot-containing composition.

### First Embodiment

### 1. Quantum-Dot-Containing Composition

A quantum-dot-containing composition according to the present disclosure contains: either quantum dots each having a surface provided with only one equivalent crystal plane, or quantum dots each having a surface provided with two or more different equivalent crystal planes; and one selected from (A), (B), and (C) below.

(A) Two or more compounds.

(B) One or more compounds containing a halogen or a chalcogen, and single atoms formed of one or more halogens or chalcogens.

(C) Single atoms formed of two or more halogens or chalcogens.

Here, the quantum dots are dots each having a maximum width of 100 nm or less. A quantum dot may have any given shape as long as the maximum width of the quantum dot is within the above range. The shape of the quantum dot shall not be limited to a spherical shape (a circular cross-section). For example, the quantum dot may have a polygonal cross-section, a bar-like three dimensional shape, a branch-like three dimensional shape, or a three dimensional shape having asperities on the surface. Alternatively, the quantum dot may have a combination of those shapes.

Each of the quantum dots may have a surface provided with only one equivalent crystal plane. The crystal plane may be a cubic crystal (001) equivalent plane, a cubic crystal (011) equivalent plane, or a cubic crystal (111) equivalent plane. Note that an (ABC) equivalent plane means {ABC}.

Furthermore, each of the quantum dots may have a surface provided with two or more different equivalent crystal planes. In such a case, the two or more different crystal planes may be a cubic crystal (001) equivalent plane and a cubic crystal (011) equivalent plane, or a cubic crystal (001) equivalent plane and a cubic crystal (111) equivalent plane. Alternatively, the two or more different crystal planes may be a cubic crystal (011) equivalent plane and a cubic crystal (111) equivalent plane, or a cubic crystal (001) equivalent plane, a cubic crystal (011) equivalent plane, and a cubic crystal (111) equivalent plane.

Such quantum dots may be known quantum dots. The quantum dots may contain at least one semiconductor material made of at least one element selected from the group consisting of, for example, cadmium (Cd), sulfur(S), tellurium (Te), selenium (Se), zinc (Zn), indium (In), nitrogen (N), phosphorus (P), arsenic (As), antimony (Sb), aluminum (Al), gallium (Ga), lead (Pb), silicon (Si), germanium (Ge), and magnesium (Mg).

Furthermore, the quantum dots may be binary-core quantum dots, tertiary-core quantum dots, quaternary-core quantum dots, core-shell quantum dots, or core-multi-shell quantum dots. Moreover, the quantum dots may contain nanoparticles doped with at least one of the above elements, or may have a composition-gradient structure.

(A) Two or more compounds, (B) one or more compounds and single atoms formed of one or more halogens or chalcogens, or (C) single atoms formed of two or more halogens or chalcogens, all of which are contained in the quantum-dot-containing composition together with the quantum dots, may be ligands of the quantum dots.

If the quantum-dot-containing composition contains (A) two or more compounds, the two or more compounds may contain halogens or chalcogens. If the quantum-dot-containing composition contains (B) one or more compounds and single atoms formed of one or more halogens or chalcogens, the one or more compounds may be halogens or a chalcogen.

The compounds containing either halogens or chalcogens may be inorganic compounds. The inorganic compounds have a lower molecular weight and a simpler structure than organic compounds. Hence, the inorganic compounds have no steric hindrance observed when coordinated to the surface of the quantum dots. As a result, the inorganic compounds can be coordinated more tightly. Furthermore, the inorganic compounds themselves are highly stable.

The compounds containing either halogens or chalcogens may be organic compounds, and, in particular, may be liner-chain organic compounds. The liner-chain organic compounds have little steric hindrance observed when coordinated to the surface of the quantum dots. As a result, the straight-chain organic compounds can be coordinated tightly to the quantum dots as the inorganic compounds.

The halogens contained in the compounds, and the single atoms that are the halogens, may be fluorine (F), chlorine (Cl), bromine (Br), or iodine (I). Alternatively, the two or more compounds may be either mixtures of fluoride and chloride or mixtures of fluoride and bromide.

Examples of the material of the halogen-containing inorganic compounds (i.e., inorganic ligands having a halogen at one end) include a salt of the halogen and a monoatomic cation. Examples of zinc include zinc fluoride (ZnF₂), zinc chloride (ZnCl₂), zinc bromide (ZnBr₂), and zinc iodide (ZnI₂). Furthermore, examples of the chalcogen-containing inorganic compound include a salt of the chalcogen and alkali metal. Examples of sodium include sodium oxide (Na₂O), sodium sulfide (Na₂S), sodium selenide (Na₂Se), and sodium telluride (Na₂Te). Note that the composition formulas described in parentheses after the compound names are examples, and the compositions may be different.

Examples of the material of the halogen-containing organic compounds (i.e., organic ligand ligands having a halogen at one end) include the materials below. Note that the examples below include chlorides having Cl at one end. The same applies to fluorides having F at one end, bromides having Br at the terminal, and iodides having I at one end.

Examples include: dioctadecyldimethylammonium chloride, ditetradecyldimethylammonium chloride, dihexadecyldimethylammonium chloride, didodecyldimethylammonium chloride, didecyldimethylammonium chloride, dioctyldimethylammonium chloride, bis(ethylhexyl)dimethylammonium chloride, octadecyltrimethylammonium chloride, oleyltrimethylammonium chloride, hexadecyltrimethylammonium chloride, tetradecyltrimethylammonium chloride, dodecyltrimethylammonium chloride, decyltrimethylammonium chloride, octyltrimethylammonium chloride, phenylethyltrimethylammonium chloride, benzyltrimethylammonium chloride, phenyltrimethylammonium chloride, benzylhexadecyldimethylammonium chloride, benzyltetradecyldimethylammonium chloride, benzyldodecyldimethylammonium chloride, benzyldecyldimethylammonium chloride, benzyloctyldimethylammonium chloride, benzyltributylammonium chloride, benzyltriethylammonium chloride, tetrabutylammonium chloride, tetrapropylammonium chloride, diisopropyldimethylammonium chloride, tetraethylammonium chloride, tetramethylammonium chloride, tetraphenylphosphonium chloride, dimethyldiphenylphosphonium chloride, methyltriphenoxyphosphonium chloride, hexadecyltributylphosphonium chloride, octyltributylphosphonium chloride, tetradecyltrihexylphosphonium chloride, tetrakis (hydroxymethyl) phosphonium chloride, tetraoctylphosphonium chloride, tetrabutylphosphonium chloride, tetramethylphosphonium chloride, and dodecylammonium chloride.

Moreover, among the listed halogen-containing organic compounds, those exemplified below and having a liner-chain structure are less likely to cause steric hindrance when coordinated to the surface of the quantum dots, and can be coordinated more tightly. Note that the same applies to fluorides, bromides, and iodides.

The examples include: octadecyltrimethylammonium chloride, oleyltrimethylammonium chloride, hexadecyltrimethylammonium chloride, tetradecyltrimethylammonium chloride, dodecyltrimethylammonium chloride, decyltrimethylammonium chloride, octyltrimethylammonium chloride, phenylethyltrimethylammonium chloride, benzyltrimethylammonium chloride, phenyltrimethylammonium chloride, tetramethylammonium chloride, tetramethylphosphonium chloride, and dodecylammonium chloride.

Examples of the material of chalcogen-containing compound (i.e., organic ligand ligands having a halogen at one end) include organic compounds containing a chalcogen such as O, S, Se, or Te. In addition, in the case where the end is a chalcogen, similar to the case where the end is a halogen, an organic compound having a linear-chain structure is less likely to cause steric hindrance, and coordinated stably.

In the quantum-dot-containing composition, a density of dangling bonds on a crystal plane of the surface of the quantum dots is 83/nm² to 240/nm², and (A) an ionic radius of the two or more compounds at one end, (B) an ionic radius of the one or more compounds at one end and an ionic radius of the single atoms formed of the one or more halogens or chalcogens, and (C) an ionic radius of the single atoms formed of the two or more halogens or chalcogens may be 0.129 nm to 0.22 nm.

### 2. Light-Emitting Element and Display Device

The light-emitting element according to the present disclosure has a light-emitting layer containing the quantum-dot-containing composition according to the present disclosure described above. The display device according to the present disclosure has the light-emitting element according to the present disclosure.

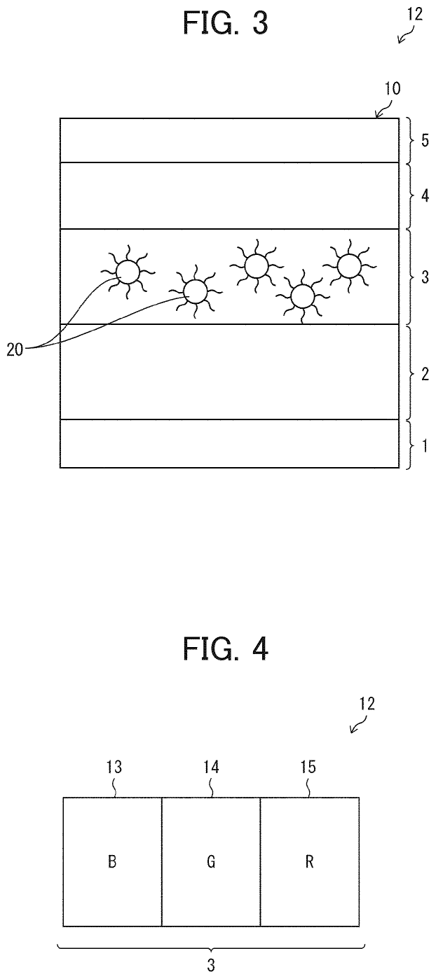

FIG. 3 is a cross-sectional view of an exemplary schematic configuration of a light-emitting element 10 according to the present disclosure included in a display device 12 according to the present disclosure. The light-emitting element 10 includes: an anode 1; a hole transport layer 2; a light-emitting layer 3; an electron transport layer 4; and a cathode 5, all of which are stacked on top of another in the stated order from below.

The anode 1 injects holes into the light-emitting layer 3 through the hole transport layer 2. Whereas, the cathode 5 injects electrons into the light-emitting layer 3 through the electron transport layer 4. Each of the anode 1 and the cathode 5 is formed of a conductive material. The anode 1 may have a function as a hole injection layer for injecting the holes into the hole transport layer 2. The cathode 5 may have a function as an electron injection layer for injecting the electrons into the electron transport layer 4.

Furthermore, of the anode 1 and the cathode 5, an electrode provided toward a light-releasing surface needs to be transparent to light. Whereas, an electrode across from the light-releasing surface may be either transparent or reflective to light. Hence, at least one of the anode 1 or the cathode 5 is formed of a light-transparent material. Moreover, either the anode 1 or the cathode 5 may be formed of a light-reflective material.

The light-transparent material may be, for example, a transparent conductive film material. Examples of the transparent conductive film material may include indium tin oxide (ITO) and indium zinc oxide (IZO). As the light-reflective material, a preferable material has a high reflectance to visible light. Examples of the light-reflective material may include: such metals as, for example, Al, Cu, Au, and Ag; and an alloy of such metals.

The light-emitting layer 3 contains a light-emitting material, and emits light by recombination of the holes transported from the anode 1 and the electrons transported from the cathode 5. The light-emitting layer 3 contains, as the light-emitting material, a quantum-dot-containing composition 20 according to the present disclosure.

The hole transport layer 2 has a function to transport the holes to the light-emitting layer 3. The hole transport layer 2 is provided in contact with the light-emitting layer 3. Note that the hole transport layer 2 may have a function to block transportation of the electrons. Furthermore, the hole transport layer 2 may also have a hole injection layer.

The electron transport layer 4 has a function to transport the electrons to the light-emitting layer 3. The electron transport layer 4 is provided in contact with the light-emitting layer 3. Note that the electron transport layer 4 may have a function to block transportation of the holes. Furthermore, the electron transport layer 4 may also have an electron injection layer.

The light-emitting element 10 has a structure including, for example, ITO/PEDOT/TFB/CdSe-quantum dot-Red/ZnO/Al. That is, between a light-transparent ITO-electrode layer and a light-reflective Al electrode, a PEDOT hole injection layer, a TFB hole transport layer, a CdSe-quantum dot-Red light-emitting layer, and a ZnO electron transport layer are stacked in the stated order from toward the ITO-electrode layer.

FIG. 4 is a diagram illustrating a configuration of a main component of the display device 12 according to the present disclosure. As illustrated in FIG. 4, the display device 12 may include a first subpixel 13 and a second subpixel 14 that emit light in different colors. A crystal plane of a surface of at least one of the quantum dots contained in the first subpixel 13 and a crystal plane of a surface of at least one of the quantum dots contained in the second subpixel 14 are different from each other. In the example in FIG. 4, the display device 12 has: the first subpixel 13 that emits light in blue; the second subpixel 14 that emits light in green; and a third subpixel 15 that emits light in red. Each of the first to third subpixels 13 to 15 contains at least one quantum dot whose surface has a crystal plane. Such crystal planes are different from one another.

The light in different colors includes a “blue light”, a “green light”, and a “red light”. In the present disclosure, the “blue light”, the “green light”, and the “red light” mean a light colored in “blue”, a light colored in “green”, and a light colored in “red” when viewed visually or on a photograph. Preferably the “blue light” has a main emission wavelength in a wavelength band of, for example, 400 nm or more and 500 nm or less. Furthermore, preferably, the “green light” has a main emission wavelength in a wavelength band of, for example, more than 500 nm and 600 nm or less. Moreover, preferably, the “red light” has a main emission wavelength in a wavelength band of, for example, more than 600 nm and 780 nm or less.

The quantum-dot-containing composition according to the present disclosure contains at least two or more kinds of: ligands; specific element groups; or specific compounds, all of which tightly coordinate to defects on the surface of the quantum dots, and readily bond to each of a plurality of crystal plane orientations terminating the surface of the quantum dots. Hence, the quantum-dot-containing composition can be shared among the first subpixel 13 and the second subpixel 14 that emit light in different colors and contain quantum dots with surfaces having different crystal planes from each other. Such a feature can reduce the kinds of required ligands, and thus reduce costs.

### 3. Method for Manufacturing Quantum-Dot-Containing Composition

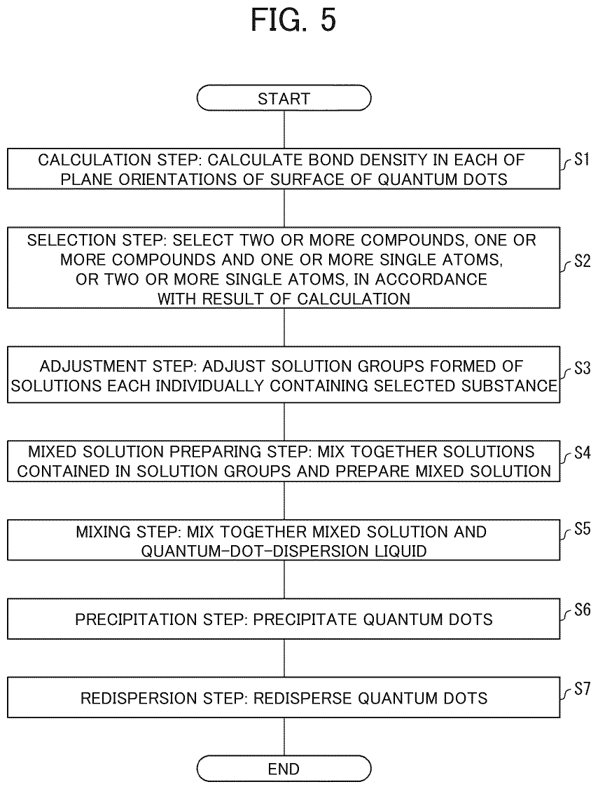

FIG. 5 is a flowchart showing an exemplary method for manufacturing the quantum-dot-containing composition according to the present disclosure. As illustrated in FIG. 5, the method for manufacturing the quantum-dot-containing composition according to the present disclosure includes: an adjustment step (S3); a mixed solution preparing step (S4); a mixing step (S5); a precipitation step (S6); and a redispersion step (S7). These steps will be described below.

The adjustment step (S3) involves adjusting: a first solution group formed of solutions each individually containing two or more compounds; a second solution group formed of solutions each individually containing one or more compounds, and single atoms formed of one or more halogens or chalcogens; and a third solution group formed of solutions each individually containing single atoms formed of two or more halogens or chalcogens.

The mixed solution preparing step (S4) involves: mixing together the first solution group, the second solution group, and the third solution group, all of which are prepared at the adjustment step (S3); and preparing a mixed solution. The mixing step (S5) involves: delivering, in the form of droplets, the mixed solution prepared at the mixed solution preparing step (S4) to either a dispersion liquid in which quantum dots are dispersed, the quantum dots each having a surface provided with only one equivalent crystal plane, or a dispersion liquid in which quantum dots are dispersed, the quantum dots each having a surface provided with two or more different equivalent crystal planes; and mixing the dispersion liquid and the mixed solution together.

The precipitation step (S6) involves precipitating the quantum dots in the dispersion liquid subjected to the mixing step (S5). The redispersion step (S7) involves redispersing, in a liquid, the quantum dots precipitated at the precipitation step (S6).

As illustrated in FIG. 5, the method for manufacturing the quantum-dot-containing composition according to the present disclosure may further include: a calculation step (S1); and a selection step (S2), both of which are carried out before the adjustment step (S3).

The calculation step (S1) involves calculating a bond density in each of plane orientations of the surface of the quantum dots. The selection step (S2) involves selecting two or more compounds, one or more compounds and single atoms formed of one or more halogens or chalcogens, or single atoms formed of two or more halogens or chalcogens, all of which have an ionic radius depending on an average distance found between the defects in each of the plane orientations and obtained by the bond density, in each of the plane orientations, calculated at the calculation step (S1). The adjustment step (S3) involves adjusting the first solution group, the second solution group, or the third solution group in accordance with the substances selected at the selection step (S2).

### 4. Advantageous Effects

As can be seen, this embodiment uses ligands, a specific element group, or a specific compound, all of which tightly coordinate to defects on the surface of the quantum dots and readily bonds to each of the plurality of crystal plane orientations terminating the surface of the quantum dots. Such a feature can increase the quantum yield of the quantum dot solution and enhance the EQE of the light-emitting element.

### Second Embodiment

Described below as a second embodiment in more detail will be a quantum-dot-containing composition and a light-emitting element according to the present disclosure with reference to specific substances.

### 1. Examples of Ideal Quantum Dots and Halogen Ligands

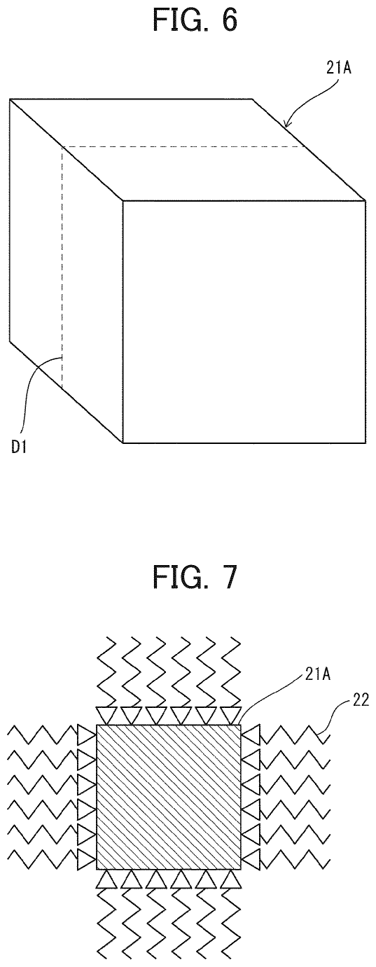

Described first is a state in which halogen ligands are coordinated to ideal quantum dots. FIG. 6 is a perspective view of an ideal quantum dot 21A with all the surfaces terminated with (001) equivalent planes. In this case, the quantum dot 21A is a cube, and because crystal planes are equivalent in all orientations, the defect density is the same among the planes. When the ideal quantum dot 21A is viewed in the cross-section indicated by the broken line D1, the surfaces in the four orientations are equivalent, and thus one kind of halogen ligands can be coordinated to, and deactivate, the surface defects.

This state is illustrated in FIG. 7. FIG. 7 is an image showing a state of halogen ligands viewed in a cross-section indicated by a broken line D1 in FIG. 6. Halogen ligands 22 each have: a zigzag portion serving as a body of an organic ligand; and a triangular (A) portion serving as a kind of halogen at one end.

In the case of the ideal quantum dot 21A, as illustrated in FIG. 7, each of the halogen ligands 22 with the one kind of halogen (A) at one end has one end, with the one kind of halogen, coordinated to a surface of the quantum dot 21A. The reason why the one kind of halogen is coordinated is because the halogen having a high electronegativity forms a bond with an unpaired electron of a defect of the surface. As can be seen, the ideal quantum dot 21A exhibits an improvement in quantum yield even with one kind of halogen ligands.

### 2. Example of Typical Quantum Dots and Halogen Ligands

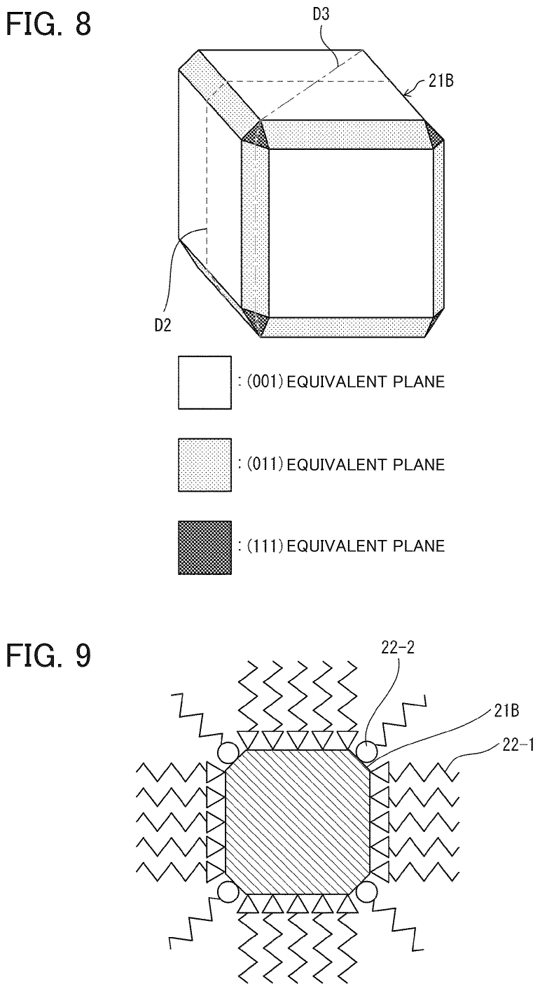

Most of actual quantum dots are terminated with two or more different crystal planes. Hence, as illustrated in FIG. 8, each of the quantum dots has (001) equivalent planes, (011) equivalent planes, and (111) equivalent planes. FIG. 8 is a perspective view of an actual quantum dot 21B having (001) equivalent planes, (011) equivalent planes, and (111) equivalent planes. Among the three kinds of equivalent planes, a (111) equivalent plane is commonly remarkably narrower than the other two kinds of planes because the crystal typically grows fast in the (111) equivalent plane. Hence, in the case of the shape illustrated in FIG. 8, the ligands can be hardly coordinated to the (111) equivalent planes. Thus, the (111) equivalent planes can be ignored.

In the case of the actual quantum dot, the ionic radius of a halogen readily coordinated is greater in the order of the (011) equivalent planes, the (001) equivalent planes, and the (111) equivalent planes. (See the table in FIG. 1.) Hence, one kind of halogen ligands are insufficient for deactivating the defects in any of plane orientations. Thus, as to the actual quantum dot, two or more kinds of halogen ligands are mixed together for use. Such a feature can obtain a quantum yield higher than a known quantum yield.

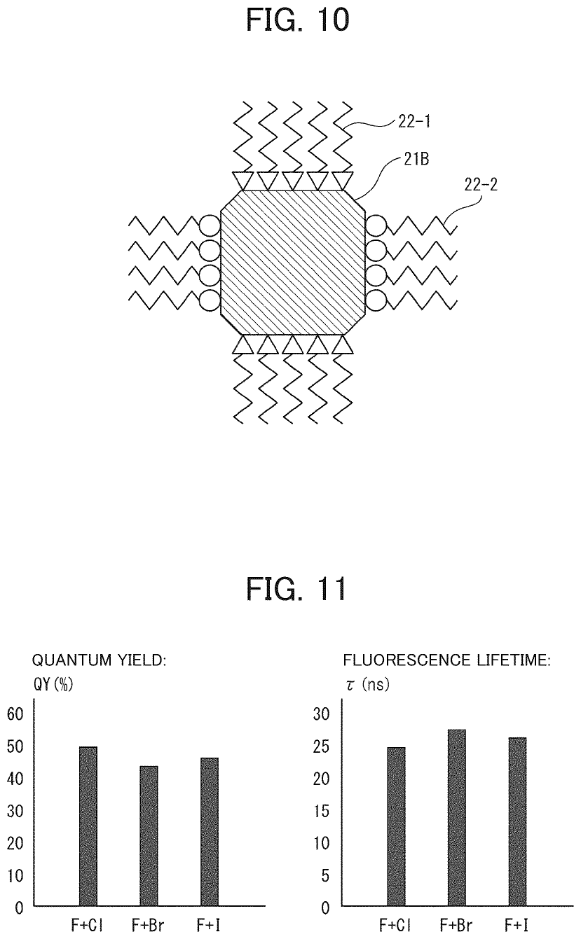

FIG. 9 is an image showing a state of halogen ligands viewed in a cross-section indicated by a broken line D2 in FIG. 8. FIG. 10 is an image showing a state of halogen ligands viewed in a cross-section indicated by a dot-and-dash line D3 in FIG. 8. FIGS. 9 and 10 show halogen ligands 22-1 each having: one kind of halogen (Δ) at one end, and halogen ligands 22-2 each having another kind of halogen (○) at one end. The halogen denoted by the symbol “○” is, for example, F having a small ionic radius, and the halogen denoted by the symbol “Δ” is, for example, Cl larger in ionic radius than F.

### 3. Steps of How Multiple Kinds of Halogen Ligands Are Coordinated to Quantum Dots

Steps will be described of how multiple kinds of halogen ligands are coordinated to quantum dots.

Step 1: First, ZnF₂, ZnCl₂, ZnBr₂, and ZnI₂ are each adjusted to have an amount of 0.4 M/L and added to ethanol, so that a ZnF₂-ethanol solution, a ZnCl₂-ethanol solution, a ZnBr₂-ethanol solution, and a ZnI₂-ethanol solution are prepared (i.e., the adjustment step in FIG. 5).

Step 2: A solution of InP quantum dots is diluted 1.5 times with hexane.
Step 3: The diluted quantum dot solution and ethanol are further mixed together in equal amount, and the mixture is centrifuged so that the quantum dots are precipitated.
Step 4: A supernatant fluid is removed from the solution in which the quantum dots are precipitated. After that, cyclohexane in an equal amount to the solvent at Step 2 is added to the solution to redisperse the quantum dots.
Step 5: At least two of the ZnF₂-ethanol solution, the ZnCl₂-ethanol solution, the ZnBr₂-ethanol solution, and the ZnI₂-ethanol solution are mixed together to prepare a mixed solution (i.e., the mixed solution preparing step in FIG. 5).
Step 6: The mixed solution prepared at Step 5 is added in the form of droplets to the quantum dot solution in which the quantum dots are redispersed, and the mixed solution and the quantum dot solution are mixed together (i.e., the mixing step in FIG. 5). A concentration of halogens is controlled with the mixing ratio of an ethanol solution serving as each of the halogen materials at Step 5 and with the amount of droplets at Step 6.
Step 7: Quantum dots are precipitated by the same step as Step 3 (the precipitation step in FIG. 5).
Step 8: Octane is mixed to redisperse the quantum dots so as to obtain a predetermined quantum dot concentration (the redispersion step in FIG. 5).

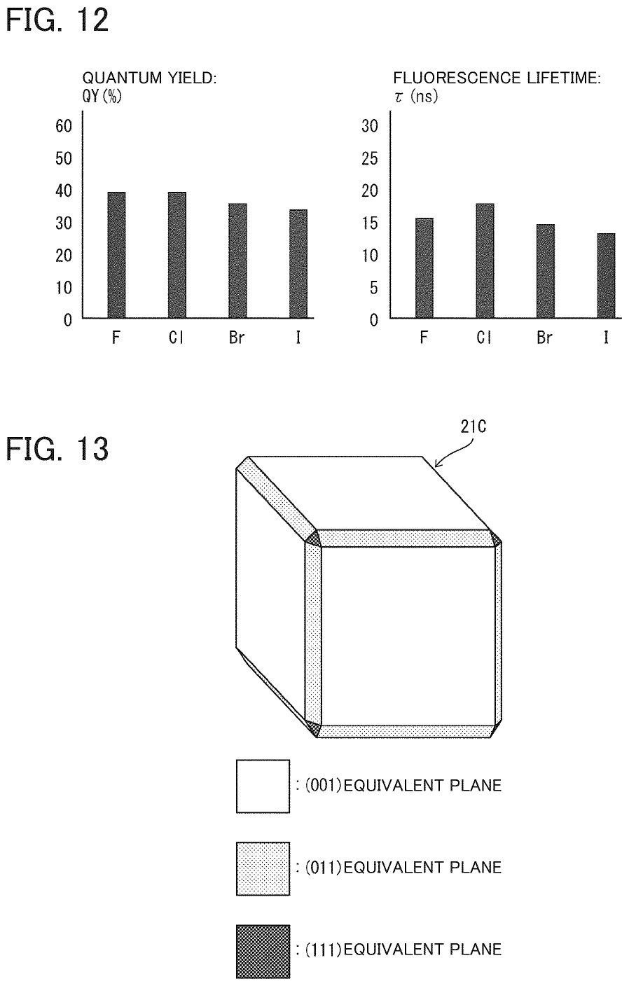

FIG. 11 shows a result of evaluating the quantum dot solutions containing the halogen ligands obtained at the above steps. FIG. 11 is a pair of graphs showing a result of measuring a quantum yield (QY) and a fluorescence lifetime (τ) of quantum dot solutions in an example in which F ligands and halogen ligands other than the F ligands are mixed together and applied to InP quantum dots. The InP quantum dots are, specifically, quantum dots having a core/ZnS-shell structure and emitting a green light. Note that, in this example, the quantum dot concentration is set to 20 mg/cm³ at Step 8.

Whereas, FIG. 12 is a pair of graphs showing a result of measuring a quantum yield (QY) and a fluorescence lifetime (τ) of quantum dot solutions in a comparative example in which various kinds of halogen ligands are applied alone to InP quantum dots. The InP quantum dots are, specifically, quantum dots having a core/ZnS-shell structure and emitting a green light. Note that, also in the comparative example, the quantum dot concentration is set to 20 mg/cm³ at Step 8.

As shown in FIG. 12, the halogen ligand solutions each containing one of F, Cl, Br and I alone have a quantum yield of approximately 40% at most. Whereas, FIG. 11 shows that the halogen ligand solutions each containing a mixture of F with one of Cl, Br, and I exhibit an increase in a quantum yield to approximately 50%.

Furthermore, as shown in FIG. 12, the halogen ligand solutions each containing one of F, Cl, Br and I alone have a fluorescence lifetime of no longer than 18 ns at most. Whereas, FIG. 11 shows that the halogen ligand solutions each containing a mixture of F with one of Cl, Br, and I has a fluorescence lifetime of over 25 ns. As to a combination of F and Br, the fluorescence lifetime reaches as long as 27 ns.

FIG. 13 is a perspective view of another actual quantum dot 21C having (001) equivalent planes, (011) equivalent planes, and (111) equivalent planes. The quantum dot illustrated in FIG. 13 is basically the same in shape as the actual quantum dot 21B illustrated in FIG. 8. The shape is terminated in three directions of the (001) equivalent planes, the (011) equivalent planes, and the (111) equivalent planes. However, the (011) equivalent planes and the (111) equivalent planes are relatively narrower than the (001) equivalent planes, and ligands coordinated to the (011) equivalent planes and the (111) equivalent planes are extremely small in amount, and thus, the ligands cannot substantially be coordinated to these two kinds of planes.

### Third Embodiment

Described below as a third embodiment will be a relationship between surface defect density and halogens likely to be preferentially coordinated.

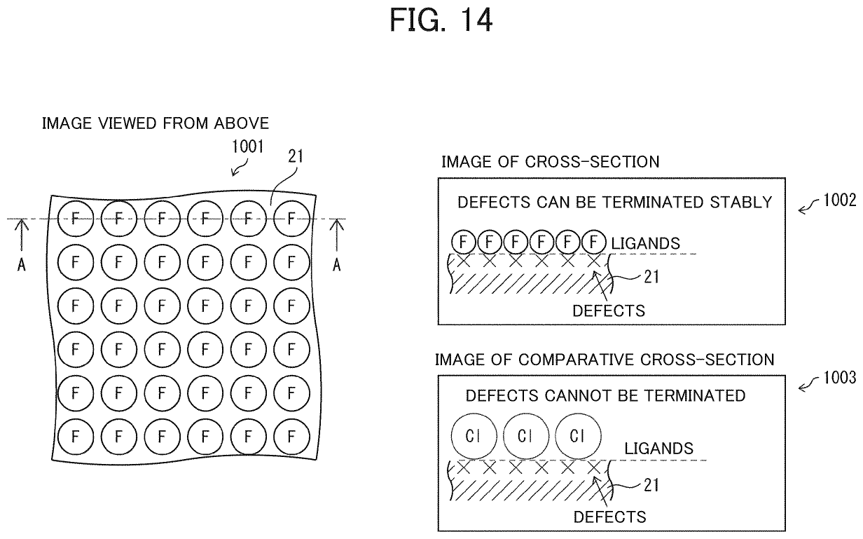

FIG. 14 is a diagram illustrating a relationship between defect density and kinds of halogens likely to be coordinated, showing a case where the defect density is high. In FIG. 14, a diagram denoted by a reference numeral 1001 is an image viewed from above, showing how the halogens (F) with a small ionic radius are coordinated to a surface, of a quantum dot 21, with high defect density. A diagram denoted by a reference numeral 1002 is an image of a cross-section taken along line A-A in the diagram denoted by the reference numeral 1001. A diagram denoted by a reference numeral 1003 is an image of a cross-section taken along line A-A, showing how halogens (Cl) with a large ionic diameter are coordinated to a surface with high defect density. In the diagrams denoted by reference numerals 1002 and 1003, defects are denoted by signs “×”.

When the defect density is high, an average distance between the defects is short. For these defects, as shown in the diagrams denoted by the reference numerals 1001 and 1002, F ligands with a small ionic radius are used. Thus, ideally, all the defects are terminated. Whereas, as shown in the diagram denoted by the reference numeral 1003, if Cl ligands larger in ionic radius than the F ligands are coordinated to the defects with a short average distance therebetween, the Cl ligands might not be coordinated and an active defect could be left unterminated.

That is, if the average distance between the defects is short, the defects are coordinated with halogens having a small ionic radius (e.g., the F halogens) in order to be stably deactivated. Such a feature can stably deactivate the defects.

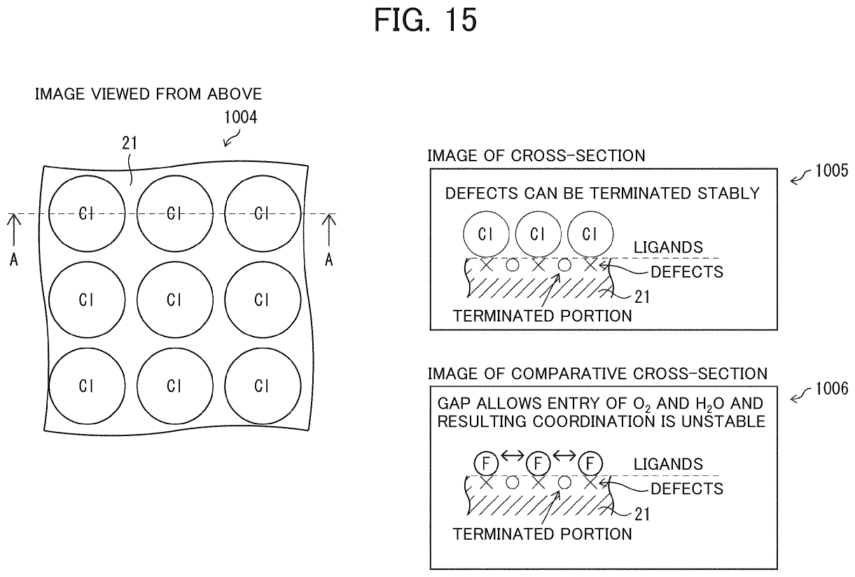

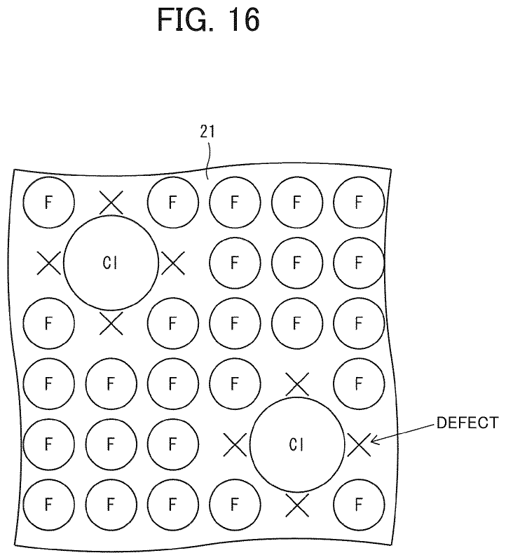

FIG. 15 is a diagram illustrating a relationship between defect density and kinds of halogens likely to be coordinated, showing a case where the defect density is low. In FIG. 15, a diagram denoted by a reference numeral 1004 is an image viewed from above, showing how the halogens (Cl) with a large ionic radius are coordinated to a surface, of a quantum dot 21, with low defect density. A diagram denoted by a reference numeral 1005 is an image of a cross-section taken along line A-A in the diagram denoted by the reference numeral 1004. A diagram denoted by a reference numeral 1006 is an image of a cross-section taken along line A-A, showing how halogens (F) with a small ionic diameter are coordinated to a surface with low defect density. In the diagrams denoted by reference numerals 1005 and 1006, defects are denoted by signs “x” and terminated portions are denoted by signs “.”.

When the defect density is low, an average distance between the defects is long. For these defects, as shown in the diagrams denoted by the reference numerals 1004 and 1005, Cl ligands with a large ionic radius are used. Thus, all the defects are terminated. Whereas, as shown in the diagram denoted by the reference numeral 1006, if F ligands smaller in ionic radius than the Cl ligands are coordinated to the defects with a short average distance therebetween, the F ligands are distant from each other. Hence, when the adjacent ligands are distant from each other, the gap between the ligands allows entry of, for example, O₂ and H₂O, and the resulting coordination is unstable.

That is, if the average distance between the defects is long, the defects are coordinated with halogens having a large ionic radius (e.g., the Cl halogens) in order to be stably deactivated. Such a feature can stably deactivate the defects. Furthermore, the feature reduces the gap between the halogens, thereby achieving an advantageous effect of preventing the quantum dots from coming into contact with substances such as O₂ or H₂O that cause quenching of the quantum dots.

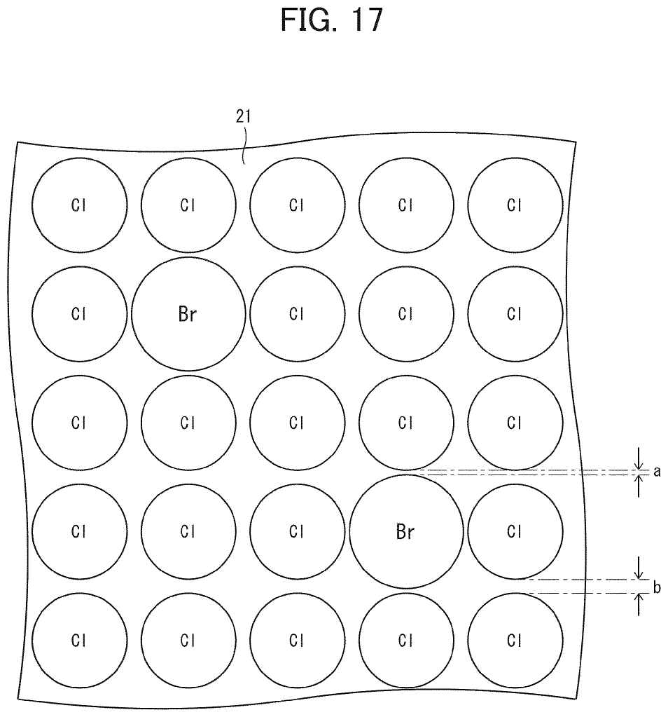

FIG. 16 is a diagram showing an image of a state in which two kinds of halogens are coordinated to a surface having high defect density, as viewed from the top. In this state, halogens F serving as first halogens are coordinated to a surface having high defect density. The halogens F are partially substituted with halogens Cl serving as second halogens and having a large ionic radius. In this state, F tightly coordinates to the defects. Whereas, Cl loosely bonds to the defects. However, four defects “×” near the second halogens Cl can be stabilized by surrounding Cl.

Note that the first and second halogens having different ionic radii cannot be uniformly distributed simultaneously. The first halogens matching the defect density can be coordinated densely. Whereas, the second halogens not matching the defect density can be coordinated only coarsely. Hence, a large amount of the first halogens and a small amount of the second halogens can be simultaneously coordinated to the quantum dots of this example.

FIG. 17 is a diagram showing an image of a state in which two kinds of halogens having slightly different ionic radii are coordinated to a surface having low defect density, as viewed from the top. In this state, halogens Cl serving as first halogens are coordinated to a surface having low defect density. The halogens Cl are partially substituted with halogens Br serving as second halogens and having a larger ionic radius. In this case, the first halogens (Cl) and the second halogens (Br) do not have a large difference in ionic radius. Hence, a second halogen can be coordinated to one defect with the same tightness as a first halogen. However, a distance “a” between the second halogen and the first halogens surrounding the second halogen is narrower than a distance “b” between the first halogens because of the difference in ionic radius, although the difference is small. Hence, charges are distributed differently around the defects to which the second halogens are coordinated, such that the second halogens can be coordinated only coarsely.

As can be seen, in any case, even though at least two kinds of halogen ligands can be mixed together and coordinated, a concentration of the second halogens is significantly lower than a concentration of the first halogens. For example, a concentration ratio of the first halogens to the second halogens is approximately 1000 to 1.

The disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the disclosure. Moreover, the technical aspects disclosed in each embodiment may be combined to achieve a new technical feature.

1. A quantum-dot-containing composition, comprising:
either quantum dots each having a surface provided with only one equivalent crystal plane, or quantum dots each having a surface provided with two or more different equivalent crystal planes; and
one selected from (A), (B) and (C) below: (A) two or more compounds; (B) one or more compounds, and single atoms formed of one or more halogens or chalcogens; and (C) single atoms formed of two or more halogens or chalcogens.

2. The quantum-dot-containing composition according to claim 1,
wherein each of the quantum dots has a surface provided with only one equivalent crystal plane that is a cubic crystal (001) equivalent plane, a cubic crystal (011) equivalent plane, or a cubic crystal (111) equivalent plane.

3. The quantum-dot-containing composition according to claim 1,
wherein each of the quantum dots has a surface provided with two or more different equivalent crystal planes.

4. The quantum-dot-containing composition according to claim 3,
wherein the two or more different crystal planes are a cubic crystal (001) equivalent plane and a cubic crystal (011) equivalent plane.

5. The quantum-dot-containing composition according to claim 3,
wherein the two or more different crystal planes are a cubic crystal (001) equivalent plane and a cubic crystal (111) equivalent plane.

6. The quantum-dot-containing composition according to claim 3,
wherein the two or more different crystal planes are a cubic crystal (011) equivalent plane and a cubic crystal (111) equivalent plane.

7. The quantum-dot-containing composition according to claim 3,
wherein the two or more different crystal planes are a cubic crystal (001) equivalent plane, a cubic crystal (011) equivalent plane, and a cubic crystal (111) equivalent plane.

8. The quantum-dot-containing composition according to claim 1,
wherein the two or more compounds contain halogens or chalcogens.

9. The quantum-dot-containing composition according to claim 1,
wherein the one or more compounds contain halogens or chalcogens.

10. The quantum-dot-containing composition according to claim 1,
wherein the compounds containing either halogens or chalcogens are inorganic compounds.

11. The quantum-dot-containing composition according to claim 1,
wherein the compounds containing either halogens or chalcogens are liner-chain organic compounds.

12. The quantum-dot-containing composition according to claim 1,
wherein the halogens contained in the compounds are fluorine, chlorine, bromine, or iodine.

13. The quantum-dot-containing composition according to claim 1,
wherein the single atoms serving as the halogens are fluorine, chlorine, bromine, or iodine.

14. The quantum-dot-containing composition according to claim 8,
wherein the two or more compounds are either mixtures of fluoride and chloride or mixtures of fluoride and bromide.

15. The quantum-dot-containing composition according to claim 1,
wherein (A) the two or more compounds, (B) the one or more compounds, and the single atoms formed of the one or more halogens or chalcogens; and (C) the single atoms formed of the two or more halogens or chalcogens are ligands of the quantum dots.

16. The quantum-dot-containing composition according to claim 1,
wherein a density of dangling bonds on a crystal plane of the surface of the quantum dots is 83/nm² to 240/nm², and
(A) an ionic radius of the two or more compounds at one end, (B) an ionic radius of the one or more compounds at one end and an ionic radius of the single atoms formed of the one or more halogens or chalcogens, and (C) an ionic radius of the single atoms formed of the two or more halogens or chalcogens are 0.129 nm to 0.22 nm.

17. A light-emitting element comprising a light-emitting layer containing the quantum-dot-containing composition according to claim 1.

18. A display device comprising the light-emitting element according to claim 17.

19. (canceled)

20. A method for manufacturing a quantum-dot-containing composition, the method comprising:
an adjustment step of adjusting: a first solution group formed of solutions each individually containing two or more compounds; a second solution group formed of solutions each individually containing one or more compounds, and single atoms formed of one or more halogens or chalcogens; and a third solution group formed of solutions each individually containing single atoms formed of two or more halogens or chalcogens;
a mixed solution preparing step of mixing together the first solution group, the second solution group, and the third solution group, all of which are prepared at the adjustment step; and preparing a mixed solution;
a mixing step of: delivering, in a form of droplets, the mixed solution prepared at the mixed solution preparing step to either a dispersion liquid in which quantum dots are dispersed, the quantum dots each having a surface provided with only one equivalent crystal plane, or a dispersion liquid in which quantum dots are dispersed, the quantum dots each having a surface provided with two or more different equivalent crystal planes; and mixing the dispersion liquid and the mixed solution together;
a precipitation step of precipitating the quantum dots in the dispersion liquid subjected to the mixing step; and
a redispersion step of redispersing, in a liquid, the quantum dots precipitated at the precipitation step.

21. The method for manufacturing the quantum-dot-containing composition according to claim 20, further comprising
a calculation step and a selection step, both of which are carried out before the adjustment step,
wherein the calculation step involves calculating a bond density in each of plane orientations of the surface of the quantum dots,
the selection step involves selecting two or more compounds, single atoms formed of one or more halogens or chalcogens, or single atoms formed of two or more halogens or chalcogens, all of which have an ionic radius depending on an average distance found between defects in each of the plane orientations and obtained by the bond density, in each of the plane orientations, calculated at the calculation step, and
the adjustment step involves adjusting the first solution group, the second solution group, or the third solution group in accordance with substances selected at the selection step.
